(19) United States
(12) Patent Application Publication
(10) Pub. No.: US 2022/0056213 A1
(43) Pub. Date: Feb. 24, 2022

(54) LOSS-DISSIPATION FLEXIBLE COPPER CLAD LAMINATE, MANUFACTURING METHOD THEREOF, AND ELECTRONIC DEVICE

(71) Applicant: NATIONAL CHUNGHSING UNIVERSITY, Taichung City (TW)

(72) Inventors: Ching-Hsuan LIN, Taichung City (TW); Wen-Chang CHEN, Taipei City (TW); Wan-Ling HSIAO, Changhua County (TW); Sudhir Kumar Reddy KAMANI, Taichung City (TW)

(21) Appl. No.: 17/445,196

(22) Filed: Aug. 17, 2021

(30) Foreign Application Priority Data
Aug. 19, 2020 (TW) 109128303

(51) Int. Cl. C08G 73/10; C09D 179/08; H05K 1/03; H05K 1/02

(52) U.S. Cl. CPC C08G 73/1032; C09D 179/08; H05K 2203/0759; H05K 1/0298; H05K 2201/0358; H05K 1/0393

(57) ABSTRACT

The present disclosure provides a low-dissipation flexible copper clad laminate, which includes a copper foil and a polyimide film. The polyimide film is attached to the copper foil. The polyimide film includes a polyimide, and the polyimide has a structure represented by formula (I). Formula (I) is defined as in the specification.

### RELATED APPLICATIONS

This application claims priority to Taiwan Application Serial Number 109128303, filed Aug. 19, 2020, which is herein incorporated by reference.

### BACKGROUND

### Technical Field

The present disclosure relates to a flexible copper clad laminate, a manufacturing method thereof and an electronic device. More particularly, the present disclosure relates to a low-dissipation flexible copper clad laminate, a manufacturing method thereof and an electronic device.

### Description of Related Art

Since 2015, the International Telecommunication Union (ITU) is officially announced the vision of 5^{th} Generation Mobile Network, all relevant units have successively developed the new technologies and materials. Furthermore, for the new generation of communication networks, it must be achieved the expectances, such as the high transmission rate, the high stability, the low latency and the low transmission loss, at the high frequencies.

The printed circuit board (PCB) is mainly used in the electronic products, such as communications, automobiles and semiconductors, to fix the integrated circuit (IC) and other electronic components, and use the copper wire to connect, so that the electronic signals can be transmitted between different components. According to the known literature, the signal transmission rate (Vₚ) is inversely proportional to the square root of the dielectric constant (Dₖ), as shown in equation (1); and the signal transmission loss (L) is proportional to the dissipation factor (D_{f}) and the square root of the dielectric constant (Dₖ), as shown in equation (2). Therefore, if it is to become a new generation of the high-frequency communication substrate, the materials thereof must have the excellent thermal properties, electrical properties, high chemical resistance and low humidity. In order to achieve the high transmission rate and the low transmission loss, reducing the dielectric constant (Dₖ) and the dissipation factor (D_{f}) of the materials are the goals of development.

$$\begin{matrix}{V}_{p} = C / \sqrt{{D}_{k}} , & equation ( 1 ) \\ L = K \times ( \frac{f}{C} ) \times {D}_{f} \times \sqrt{{D}_{k}} . & equation ( 2 )\end{matrix}$$

The common printed circuit board includes the flexible printed circuit board, which is generally formed by attached the polyimide and the copper foil, and the electrical property is closely related to the polyimide. The most common polyimide on the market is Kapton of DuPont, and its dissipation factor is about 0.016. Therefore, the conventional polyimide has no longer satisfied the requirements of the high-frequency signal transmission and the high-speed operation of the circuit board.

Therefore, how to synthesize a polyimide with low dissipation factor, and the prepared flexible copper clad laminate can be applied in the manufacture of the high-frequency transmission printed circuit board, which is the goal of the relevant industry.

### SUMMARY

According to one aspect of the present disclosure, a low-dissipation flexible copper clad laminate is provided. The low-dissipation flexible copper clad laminate includes a copper foil and a polyimide film. The polyimide film is attached to the copper foil, wherein the polyimide film includes a polyimide, and the polyimide has a structure represented by formula (I):

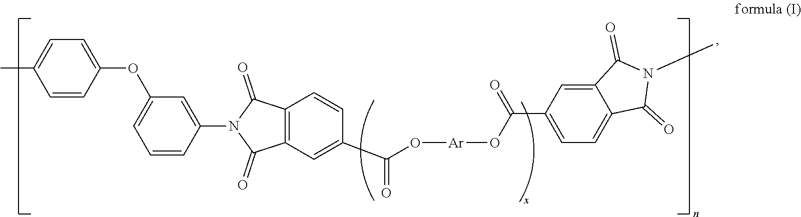

wherein Ar is a divalent organic group containing an aromatic ring, x is 0 or 1, n is an average value, and n is greater than 30 and less than 500.

According to another aspect of the present disclosure, a manufacturing method for a low-dissipation flexible copper clad laminate according to the aforementioned aspect includes steps as follows. A mixing step is performed, wherein a diamine monomer represented by formula (i) is dissolved in an organic solvent, and then a dianhydride monomer represented by formula (ii) is added to form a polyamic acid solution:

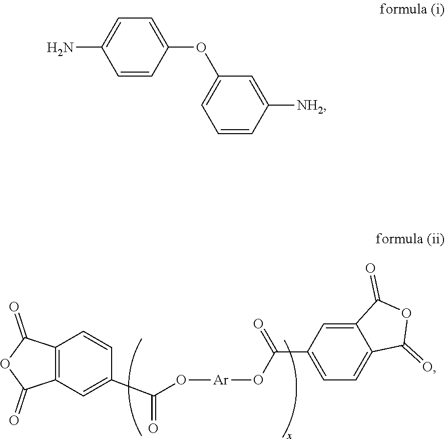

wherein Ar is the divalent organic group containing the aromatic ring, x is 0 or 1. A condensation reaction is performed, wherein the polyamic acid solution is coated on the copper foil, and performed the heat and ring-closing to obtain the low-dissipation flexible copper clad laminate.

According to further another aspect of the present disclosure, an electronic device is provided. The electronic device includes the low-dissipation flexible copper clad laminate according to the aforementioned aspect.

### BRIEF DESCRIPTION OF THE DRAWINGS

The present disclosure can be more fully understood by reading the following detailed description of the embodiment, with reference made to the accompanying drawings as follows:

FIGS. 1A, 1B, 1C, 1D, 1E, 1F and 1G are schematic diagrams of an arrangement structure of molecular chains.

FIG. 2 is a single crystal XRD diagram of formula (D).

FIG. 3 is a flow chart of a manufacturing method for a low-dissipation flexible copper clad laminate according to one embodiment of the present disclosure.

### DETAILED DESCRIPTION

The present disclosure will be further exemplified by the following specific embodiments. However, the embodiments can be applied to various inventive concepts and can be embodied in various specific ranges. The specific embodiments are only for the purposes of description, and are not limited to these practical details thereof.

In the present disclosure, the compound structure can be represented by a skeleton formula, and the representation can omit the carbon atom, the hydrogen atom and the carbon-hydrogen bond. In the case that the functional group is depicted clearly in the structural formula, the depicted one is preferred.

In the present disclosure, in order to concise and smooth, “polyimide has a structure represented by formula (I)” can be represented as a polyimide represented by formula (I) or a polyimide (I) in some cases, and the other compounds or groups can be represented in the same manner.

### Polyimide

A polyimide is provided of the present disclosure, which has a structure represented by formula (I):

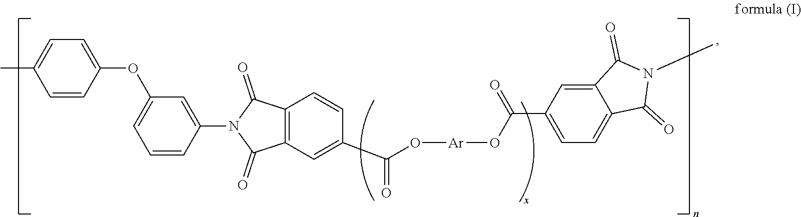

wherein Ar is a divalent organic group containing an aromatic ring, x is 0 or 1, n is an average value, and n is greater than 30 and less than 500. Specifically, Ar can be a structure represented by formula (A), formula (B) or formula (C):

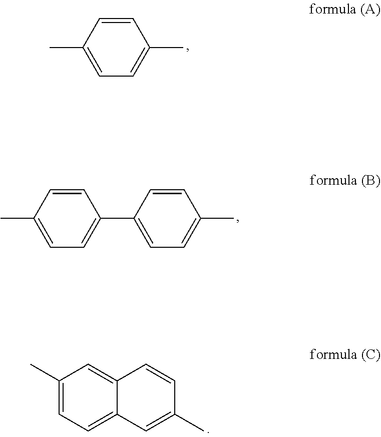

In detail, the material with the lowest dissipation factor currently on the market is liquid crystal polyester (LCP). At 10 GHz, the dissipation factor of the liquid crystal polyester can reach less than 0.002, because the liquid crystal polyester has a local ordinal arrangement and a low-polar ester group, which results its low dissipation factor characteristic. Hence, in order to achieve low dissipation factor of the polyimide, the molecular chain of the polyimide needs to have a linear characteristic, and the selected monomer must also be considered to linear.

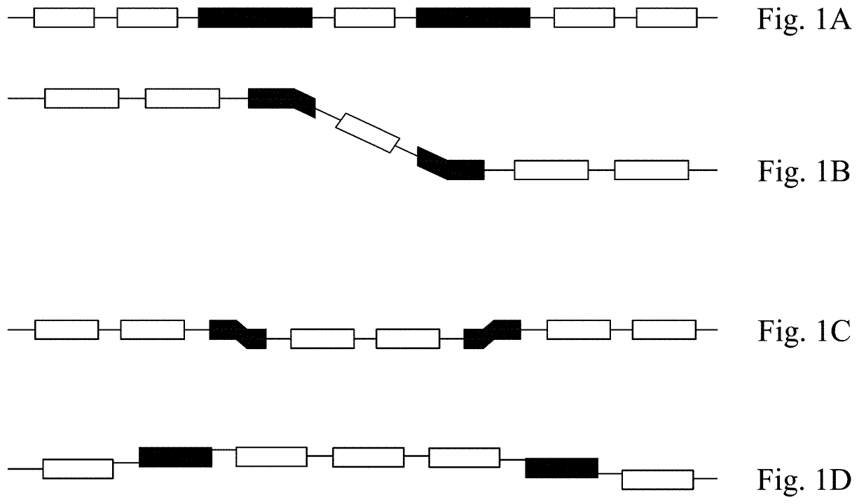

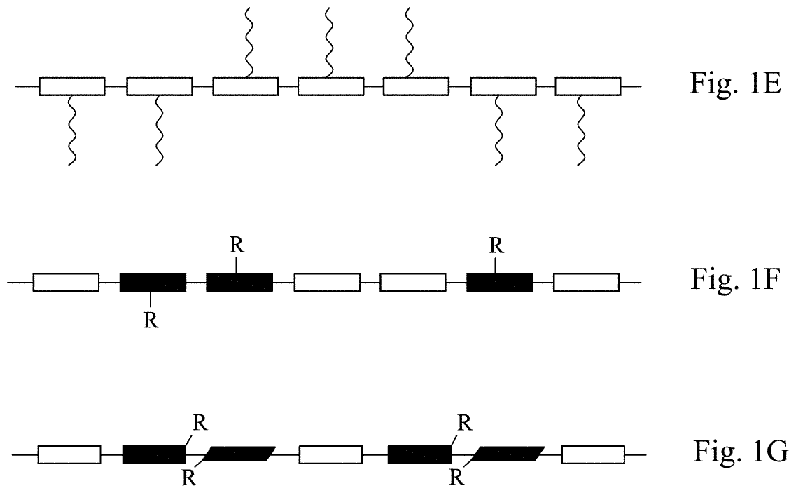

Please refer to FIGS. 1A, 1B, 1C, 1D, 1E, 1F and 1G, which are schematic diagrams of an arrangement structure of molecular chains. Specifically, if the arrangement structure of the molecular chain is too linear, it will cause to the poor processability, as shown in FIG. 1A, and the corresponding structure can be but not limited to a structure represented by formula (a-1), formula (a-2) or formula (a-3). Therefore, it is necessary to introduce non-linear or the monomer of side chain group to increase processability, as shown in FIGS. 1B, 1C, 1D, 1E, 1F and 1G, wherein R in FIGS. 1F and 1G represents a substituted group.

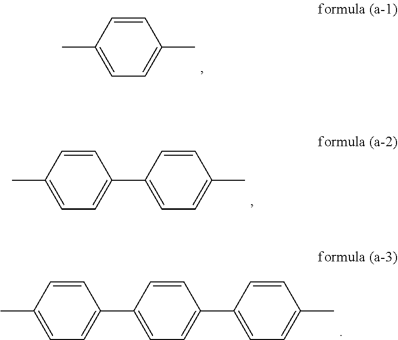

The common polyimide Kpaton (DuPont) is composed of 4,4′-oxyianiline (4,4′-ODA) and pyromellitic anhydride (PMDA). Although the molecular formulas of the liquid crystal polymer and the polyimide are different, the arrangement method of that is similar, so that the arrangement of the liquid crystal polymer can be used to simulate the molecular arrangement of the polyimide.

For example, if the polyimide molecular chain is arranged as shown in FIG. 1B, the corresponding structure can be but not limited to a structure represented by formula (b-1), formula (b-2) or formula (b-3), indicating that when 4,4′-ODA is used as the reactive monomer to react with the acid anhydride, the linearity of the polyimide molecular chain will be greatly reduced.

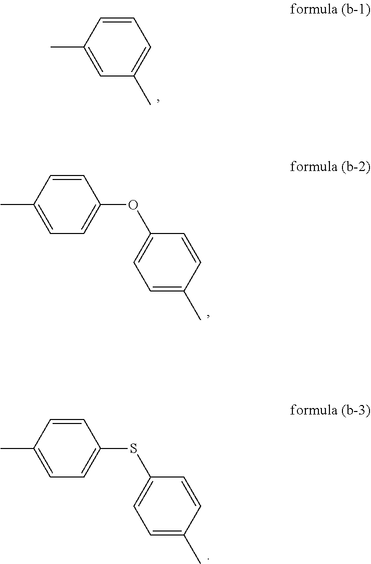

Furthermore, if the polyimide molecular chain is arranged as shown in FIG. 1C, the corresponding structure can be but not limited to a structure represented by formula (c-1) or formula (c-2), indicating that when 3,4′-oxydianiline (3,4′-ODA) or 4,4′-diaminobenzophenone is used as the reactive monomer to react with the acid anhydride, the processability compared with the arrangement structure of FIG. 1A can be improved, and the linearity of the molecular chain compared with the arrangement structure of FIG. 1B can still be maintained. However, the polarity of the carbonyl group of 4,4′-diaminobenzophenone is relatively high, which is unfavorable for the dissipation factor. The carbonyl group is an electron-withdrawing substituent, which will cause the diamine has the low reactivity and is unfavorable for polymerizing into the polymer. The polarity of the oxy group of 3,4′-ODA is relatively lower than the carbonyl group. The oxy group is an electron-donating substituent, so the diamine has the high reactivity to be good for polymerizing into the polymer. Hence, the polymerization of 3,4′-ODA and the dianhydride in the present disclosure should be satisfied with the polyimide having a linear arrangement structure.

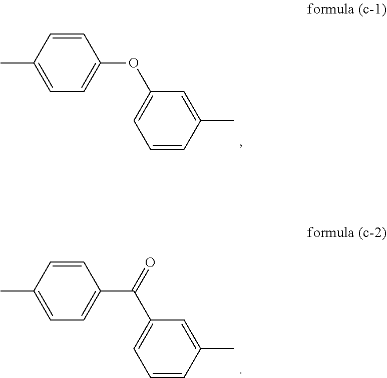

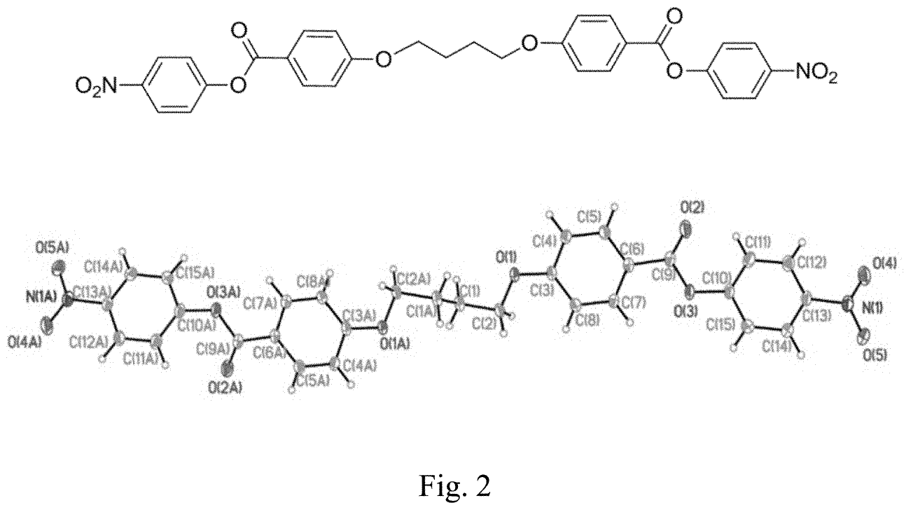

Moreover, in addition to use 3,4′-ODA as the diamine monomer, the present disclosure also intends to introduce the ester structure into the polyimide to maintain the linearity of the molecular chain. Please refer to FIG. 2, which is a single crystal XRD diagram of formula (D), wherein the formula (D) is a structure with an ester group introduced, as shown below:

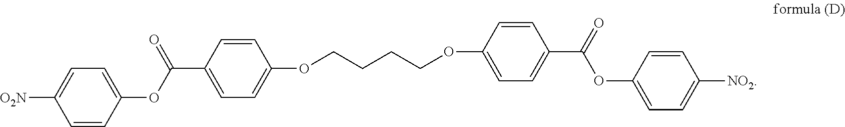 [SMILES: O=C(Oc1ccc([N+](=O)[O-])cc1)c1ccc(OCCCCOc2ccc(C(=O)Oc3ccc([N+](=O)[O-])cc3)cc2)cc1]

As known the single crystal XRD diagram in FIG. 2, the formula (D) with the introduction of the ester group structure can indeed maintain the linearity of the molecular. There are two methods to introduce the ester group, one is to introduce the ester group into the diamine, and the other is to introduce the ester group into the dianhydride.

### Polyimide Film

A polyimide film is provided of the present disclosure, which includes the aforementioned polyimide. Specifically, in the formula (I), when x is 1 and Ar is the structure represented by formula (A), the polyimide has a structure represented by formula (I-A):

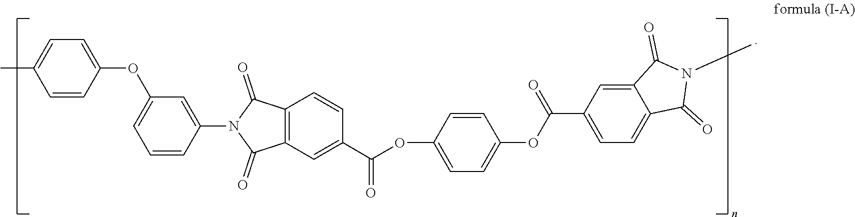

At this time, a dielectric constant of the prepared polyimide film can be 2.8 to 3.5, and a dissipation factor can be less than 0.0025.

### Flexible Copper Clad Laminate

A low-dissipation flexible copper clad laminate is provided of the present disclosure, which includes a copper foil and the aforementioned polyimide film. The polyimide film is attached to the copper foil, and the copper foil is any kind of copper foil used for flexible copper clad laminate known in the art, and will not be described herein. Hence, due to the polyimide film has the low dielectric constant and the low dissipation factor, the prepared flexible copper clad laminate has the low dissipation factor. Furthermore, when the flexible copper clad laminate is applied to the flexible circuit board, the electrical interference between the circuits will be reduced, which is favorable for avoiding the power load and the signal delay.

### Manufacturing Method for Low-Dissipation Flexible Copper Clad Laminate

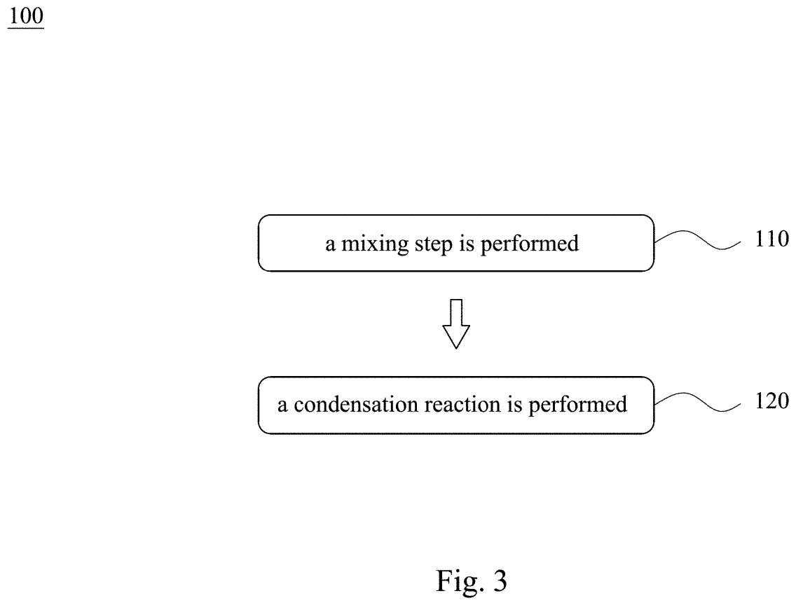

Please refer to FIG. 3, which is a flow chart of a manufacturing method for a low-dissipation flexible copper clad laminate 100 according to one embodiment of the present disclosure. In FIG. 3, the manufacturing method for the low-dissipation flexible copper clad laminate 100 includes a step 110 and a step 120.

In the step 110, a mixing step is performed, wherein a diamine monomer represented by formula (i) is dissolved in an organic solvent, and then a dianhydride monomer represented by formula (ii) is added to form a polyamic acid solution:

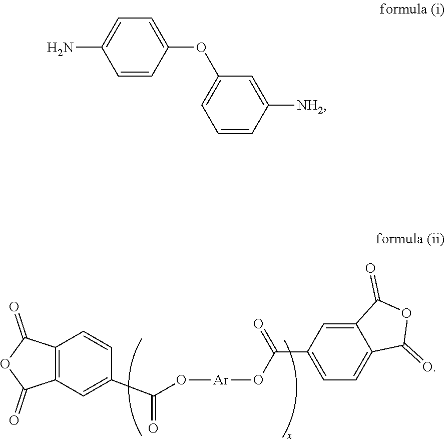

The definition of Ar and x can refer to the aforementioned paragraph, and will not be described herein.

In the step 120, a condensation reaction is performed, wherein the polyamic acid solution is coated on the copper foil, and performed the heat and ring-closing to obtain the low-dissipation flexible copper clad laminate.

Specifically, the organic solvent used in the mixing step can be but not limited to dimethylacetamide (DMAc), dimethylformamide (DMF) or N-methyl-2-pyrrolidone (NMP). However, in the mixing step, a molar ratio of the aforementioned diamine monomer represented by formula (i) to the aforementioned dianhydride monomer represented by formula (ii) can be 0.9 to 1.1. Then, in the condensation reaction, after coating the polyamic acid solution on the copper foil and heating to remove the organic solvent, the polyimide film containing the polyimide represented by formula (I) can be synthesized, and the flexible copper clad laminate formed by attaching the copper foil and the polyimide film can be obtained. The coating method can be but not limited to a knife coating method or a spin coating method.

### Electronic Device

An electronic device is provided of the present disclosure, which includes the aforementioned low-dissipation flexible copper clad laminate. The low-dissipation flexible copper clad laminate can refer to the aforementioned paragraph, and will not be described herein. The structure and manufacturing method of the electronic device is a conventional technique, and will not be described herein.

The present disclosure will be further exemplified by the following specific embodiments so as to facilitate utilizing and practicing the present disclosure completely by the people skilled in the art without over-interpreting and over-experimenting. However, the readers should understand that the present disclosure should not be limited to these practical details thereof, that is, these practical details are used to describe how to implement the materials and methods of the present disclosure and are not necessary.

### Example

Example 1: 2 g (9.988 mmol) of 3,4′-ODA diamine monomer is dissolved in 29.97 g of the dewatered DMAc (18 wt %). After the diamine monomer is completely dissolved, adding 4.5778 g (9.988 mmol) of p-Phenylene bis(trimellitate) dianhydride (TAHQ), and stirring for 24 hours under the nitrogen atmosphere. Next, controlling the thickness of the scraper to 400 μm and coating to the copper foil, then placing it at the circulating oven so as to heat to 150° C. for 20 minutes. After drying most of the solvent, the temperature is increased to 150° C. for 30 minutes, 200° C. for an hour, 250° C. for an hour, and 300° C. for an hour to obtain the single-sided flexible copper clad laminate of Example 1 for testing the heat resistant of solder float. Then, the copper clad laminate is etched to obtain the polyimide film of Example 1 for testing the electrical. The reaction scheme of Example 1 is shown in Table 1.

TABLE 1

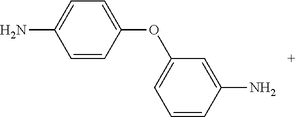 [SMILES: Nc1ccc(Oc2cccc(N)c2)cc1]

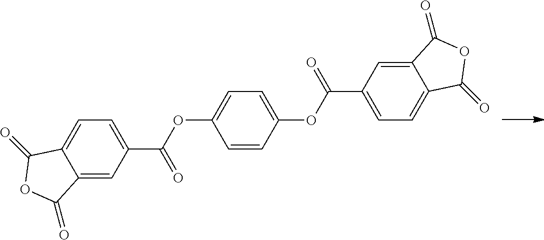 [SMILES: O=C(Oc1ccc(OC(=O)c2ccc3c(c2)C(=O)OC3=O)cc1)c1ccc2c(c1)C(=O)OC2=O]

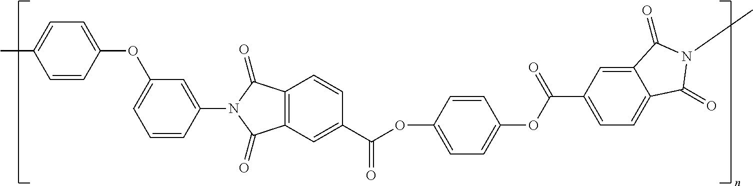

Example 2: 2 g (9.988 mmol) of 4,4′-ODA diamine monomer is dissolved in 29.97 g of the dewatered DMAc (18 wt %). After the diamine monomer is completely dissolved, adding 4.5778 g (9.988 mmol) of TAHQ dianhydride monomer, and stirring for 24 hours under the nitrogen atmosphere. The subsequent steps are the same as Example 1, and the single-sided flexible copper clad laminate of Example 2 can be obtained for testing the heat resistant of solder float. Then, the copper clad laminate is etched to obtain the polyimide film of Example 2 for testing the electrical. The reaction scheme of Example 2 is shown in Table 2.

TABLE 2

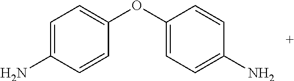 [SMILES: Nc1ccc(Oc2ccc(N)cc2)cc1]

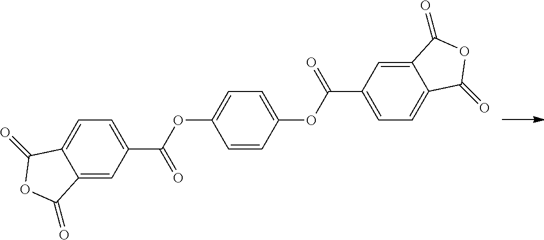 [SMILES: O=C(Oc1ccc(OC(=O)c2ccc3c(c2)C(=O)OC3=O)cc1)c1ccc2c(c1)C(=O)OC2=O]

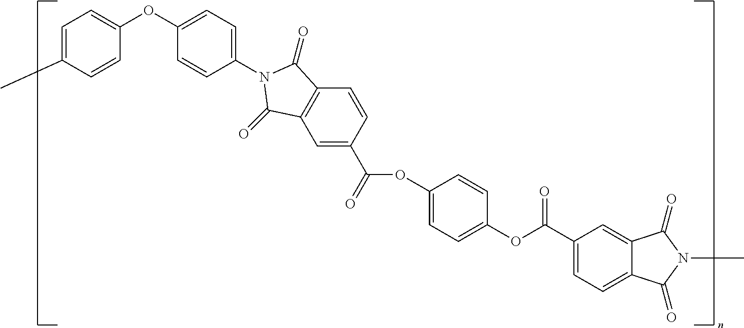

Example 3: 2 g (9.988 mmol) of 3,4′-ODA diamine monomer is dissolved in 16.71 g of the dewatered DMAc (20 wt %). After the diamine monomer is completely dissolved, adding 2.1786 g (9.988 mmol) of PMDA dianhydride monomer, and stirring for 24 hours under the nitrogen atmosphere. The subsequent steps are the same as Example 1, and the single-sided flexible copper clad laminate of Example 3 can be obtained for testing the heat resistant of solder float. Then, the copper clad laminate is etched to obtain the polyimide film of Example 3 for testing the electrical. The reaction scheme of Example 3 is shown in Table 3.

TABLE 3

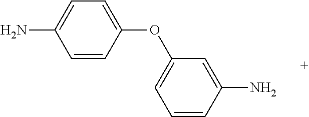 [SMILES: Nc1ccc(Oc2cccc(N)c2)cc1]

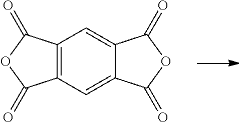 [SMILES: O=c1oc(=O)c2cc3c(=O)oc(=O)c3cc12]

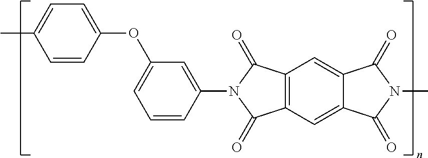

Example 4: 2 g (9.988 mmol) of 4,4′-ODA diamine monomer is dissolved in 16.71 g of the dewatered DMAc (20 wt %). After the diamine monomer is completely dissolved, adding 2.1786 g (9.988 mmol) of PMDA dianhydride monomer, and stirring for 24 hours under the nitrogen atmosphere. The subsequent steps are the same as Example 1, and the single-sided flexible copper clad laminate of Example 4 can be obtained for testing the heat resistant of solder float. Then, the copper clad laminate is etched to obtain the polyimide film of Example 4 for testing the electrical. The reaction scheme of Example 4 is shown in Table 4.

TABLE 4

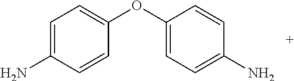 [SMILES: Nc1ccc(Oc2ccc(N)cc2)cc1]

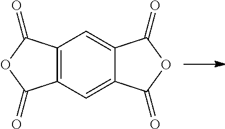 [SMILES: O=c1oc(=O)c2cc3c(=O)oc(=O)c3cc12]

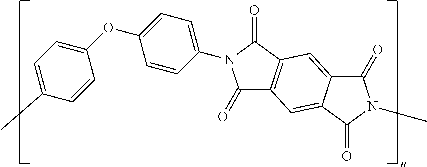

Example 5: 2 g (9.988 mmol) of 3,4′-ODA diamine monomer is dissolved in 19.75 g of the dewatered DMAc (20 wt %). After the diamine monomer is completely dissolved, adding 2.9387 g (9.988 mmol) of 3,3′,4,4′-biphenyltetracarboxylic dianhydride (BPDA), and stirring for 24 hours under the nitrogen atmosphere. The subsequent steps are the same as Example 1, and the single-sided flexible copper clad laminate of Example 5 can be obtained for testing the heat resistant of solder float. Then, the copper clad laminate is etched to obtain the polyimide film of Example 5 for testing the electrical. The reaction scheme of Example 5 is shown in Table 5.

TABLE 5

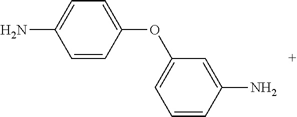 [SMILES: Nc1ccc(Oc2cccc(N)c2)cc1]

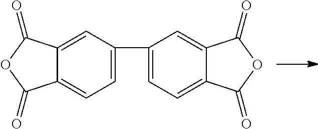 [SMILES: O=C1OC(=O)c2cc(-c3ccc4c(c3)C(=O)OC4=O)ccc21]

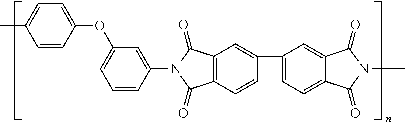

Example 6: 2 g (9.988 mmol) of 4,4′-ODA diamine monomer is dissolved in 19.75 g of the dewatered DMAc (20 wt %). After the diamine monomer is completely dissolved, adding 2.9387 g (9.988 mmol) of BPDA dianhydride monomer, and stirring for 24 hours under the nitrogen atmosphere. The subsequent steps are the same as Example 1, and the single-sided flexible copper clad laminate of Example 6 can be obtained for testing the heat resistant of solder float. Then, the copper clad laminate is etched to obtain the polyimide film of Example 6 for testing the electrical. The reaction scheme of Example 6 is shown in Table 6.

TABLE 6

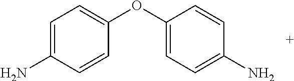 [SMILES: Nc1ccc(Oc2ccc(N)cc2)cc1]

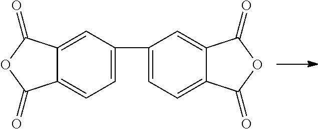 [SMILES: O=C1OC(=O)c2cc(-c3ccc4c(c3)C(=O)OC4=O)ccc21]

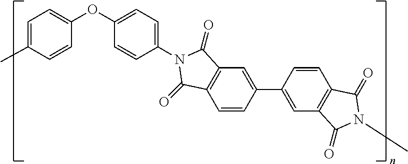

Example 7: 1 g (2.87 mmol) of 1,4-bis(4-aminobenzo-yloxy)benzene (HQ-NH₂) is dissolved in 9.08 g of the dewatered DMAc (25 wt %). After the diamine monomer is completely dissolved, adding 1.27 g (2.87 mmol) of 4,4′-(hexafluoroisopropylidene)diphthalic anhydride (6FDA), and stirring for 24 hours under the nitrogen atmosphere. The subsequent steps are the same as Example 1, and the single-sided flexible copper clad laminate of Example 7 can be obtained for testing the heat resistant of solder float. Then, the copper clad laminate is etched to obtain the polyimide film of Example 7 for testing the electrical. The reaction scheme of Example 7 is shown in Table 7.

TABLE 7

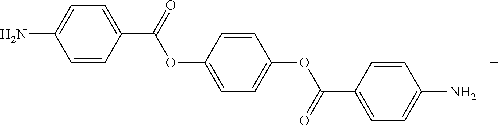 [SMILES: Nc1ccc(C(=O)Oc2ccc(OC(=O)c3ccc(N)cc3)cc2)cc1]

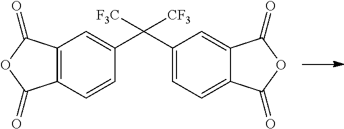 [SMILES: O=C1OC(=O)c2cc(C(c3ccc4c(c3)C(=O)OC4=O)(C(F)(F)F)C(F)(F)F)ccc21]

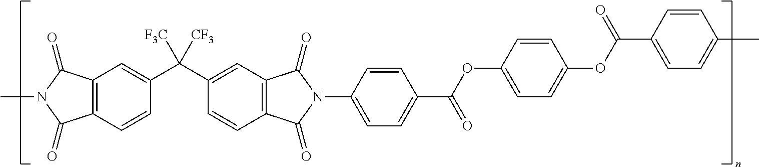

Example 8: 1 g (2.87 mmol) of bis(4-aminophenyl)terephthalate (TP-NH₂) is dissolved in 9.08 g of the dewatered DMAc (25 wt %). After the diamine monomer is completely dissolved, adding 1.27 g (2.87 mmol) of 6FDA dianhydride monomer, and stirring for 24 hours under the nitrogen atmosphere. The subsequent steps are the same as Example 1, and the single-sided flexible copper clad laminate of Example 8 can be obtained for testing the heat resistant of solder float. Then, the copper clad laminate is etched to obtain the polyimide film of Example 8 for testing the electrical. The reaction scheme of Example 8 is shown in Table 8.

TABLE 8

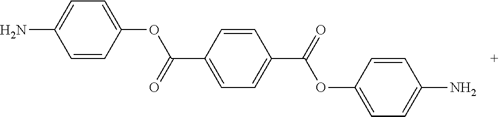 [SMILES: Nc1ccc(OC(=O)c2ccc(C(=O)Oc3ccc(N)cc3)cc2)cc1]

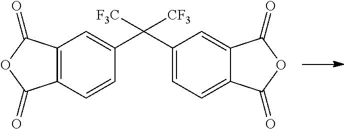 [SMILES: O=C1OC(=O)c2cc(C(c3ccc4c(c3)C(=O)OC4=O)(C(F)(F)F)C(F)(F)F)ccc21]

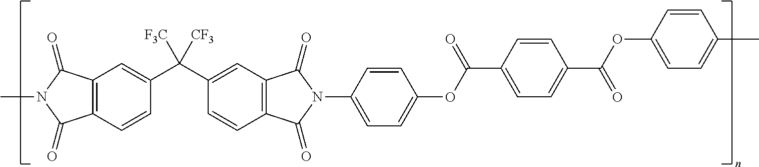

Example 9: 1 g (2.87 mmol) of TP-NH₂ diamine monomer is dissolved in 6.96 g of the dewatered DMAc (25 wt %). After the diamine monomer is completely dissolved, adding 1.32 g (2.87 mmol) of TAHQ dianhydride monomer, and stirring for 24 hours under the nitrogen atmosphere. The subsequent steps are the same as Example 1, and the single-sided flexible copper clad laminate of Example 9 can be obtained for testing the heat resistant of solder float. Then, the copper clad laminate is etched to obtain the polyimide film of Example 9 for testing the electrical. The reaction scheme of Example 9 is shown in Table 9.

TABLE 9

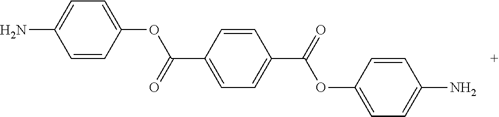 [SMILES: Nc1ccc(OC(=O)c2ccc(C(=O)Oc3ccc(N)cc3)cc2)cc1]

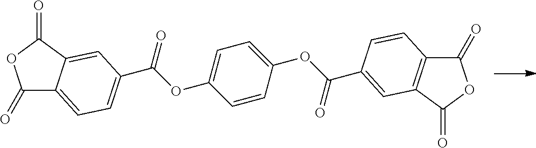 [SMILES: O=C(Oc1ccc(OC(=O)c2ccc3c(c2)C(=O)OC3=O)cc1)c1ccc2c(c1)C(=O)OC2=O]

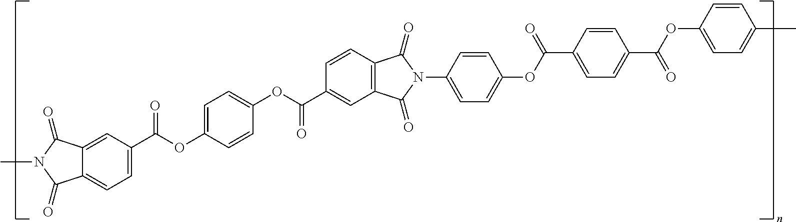

Example 10: 3.06 g (8.8 mmol) of TP-NH₂ diamine monomer is dissolved in 19.92 g of the dewatered NMP (20 wt %). After the diamine monomer is completely dissolved, adding 1.92 g (8.8 mmol) of PMDA dianhydride monomer, and stirring for 24 hours under the nitrogen atmosphere. The subsequent steps are the same as Example 1, and the single-sided flexible copper clad laminate of Example 10 can be obtained for testing the heat resistant of solder float. Then, the copper clad laminate is etched to obtain the polyimide film of Example 10 for testing the electrical. The reaction scheme of Example 10 is shown in Table 10.

TABLE 10

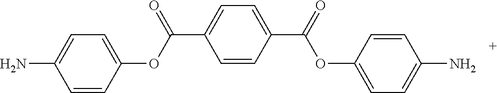 [SMILES: Nc1ccc(OC(=O)c2ccc(C(=O)Oc3ccc(N)cc3)cc2)cc1]

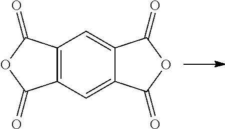 [SMILES: O=c1oc(=O)c2cc3c(=O)oc(=O)c3cc12]

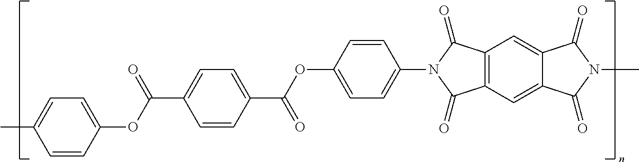

Example 11: 2 g (8.8 mmol) of 4-aminophenyl 4-aminobenzoate (APAB) is dissolved in 24.68 g of the dehydrated NMP (20 wt %). After the diamine monomer is completely dissolved, adding 7.72 g (8.8 mmol) of TAHQ dianhydride monomer, and stirring for 48 hours under the nitrogen atmosphere. The subsequent steps are the same as Example 1, and the single-sided flexible copper clad laminate of Example 11 can be obtained for testing the heat resistant of solder float. Then, the copper clad laminate is etched to obtain the polyimide film of Example 11 for testing the electrical. The reaction scheme of Example 11 is shown in Table 11.

TABLE 11

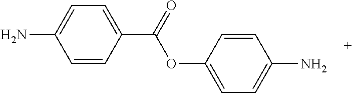 [SMILES: Nc1ccc(OC(=O)c2ccc(N)cc2)cc1]

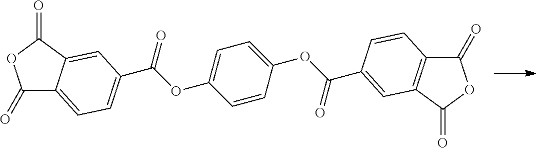 [SMILES: O=C(Oc1ccc(OC(=O)c2ccc3c(c2)C(=O)OC3=O)cc1)c1ccc2c(c1)C(=O)OC2=O]

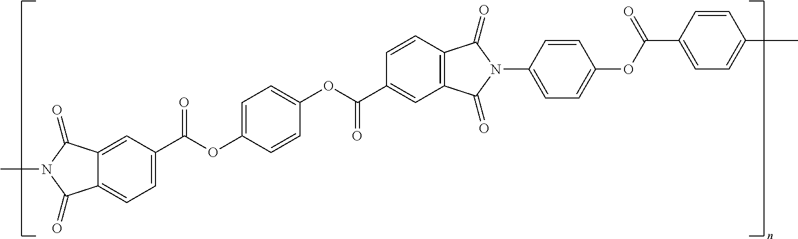

### Evaluation Test Method

Heat resistant of solder float test: the prepared single-sided flexible copper clad laminate is placed at 288° C. for solder floating for 10 seconds, and the test is performed three times to visually check the blisters or not.

Dielectric analysis method: first, the prepared polyimide film is dried and removed water at 120° C. for 1 hour, then placed at a dielectric constant analysis with 10 GHz to perform the dielectric analysis to test three times for taking the average value. The label and the model of the dielectric constant analysis is Rohde & Schwarz Taiwan Ltd./steel/ZNB20. The dielectric constant (Dₖ) and the dissipation factor (D_{f}) of the cured film is tested at 10 GHz, the cured film should be less than or equal to 350 μm. The cured film is cut to 9 cm×13 cm and measured at the room temperature.

Example 1 to Example 11 are performed the aforementioned evaluation test method, and the results are recorded in Table 12.

TABLE 12

| | | | | Heat | | |
|---|---|---|---|---|---|---|
| | | | | resistant | | |
| | | | Film | of solder | | |
| | diamine | dianhydride | forming | float | Dₖ | D_{f} |
| Example 1 | 3,4′-ODA | TAHQ | O | Pass | 3.0 | 0.0017 |
| Example 2 | 4,4′-ODA | TAHQ | O | Pass | 3.0 | 0.0023 |
| Example 3 | 3,4′-ODA | PMDA | O | Pass | 3.5 | 0.014 |
| Example 4 | 4,4′-ODA | PMDA | O | Pass | 3.5 | 0.016 |
| Example 5 | 3,4′-ODA | BPDA | O | Pass | 3.1 | 0.0043 |
| Example 6 | 4,4′-ODA | BPDA | O | Pass | 3.1 | 0.0045 |
| Example 7 | HQ-NH₂ | 6FDA | O | Pass | 3.01 | 0.016 |
| Example 8 | TP-NH₂ | 6FDA | O | Pass | 2.96 | 0.011 |
| Example 9 | TP-NH₂ | TAHQ | X | X | — | — |
| Example 10 | TP-NH₂ | PMDA | X | X | — | — |
| Example 11 | APAB | TAHQ | X | X | — | — |

It can be seen from the results in Table 12, when the dianhydride structure is fixed, the effects of 3,4′-ODA and 4,4′-ODA on the dissipation factor can be compared. For example, compared with Example 1 and Example 2, the dissipation factor is 0.0017 and 0.0023, respectively. Compared with Example 3 and Example 4, the dissipation factor is 0.014 and 0.016, respectively. Compared with Example 5 and Example 6, the dissipation factor is 0.0043 and 0.0045, respectively. It can be found that the polyimide composed of 3,4′-ODA diamine monomer has lower dissipation factor characteristic, which is related to the better linearity of 3,4′-ODA.

Furthermore, when the diamine structure is fixed, the effects of different dianhydride on the dissipation factor can be compared. For example, compared with Example 1, Example 3 and Example 5, the dissipation factor is 0.0017, 0.014 and 0.0043, respectively. Compared with Example 2, Example 4 and Example 6, the dissipation factor is 0.0023, 0.016 and 0.0045, respectively. It can be found that in the dianhydride structure, TAHQ is better than BPDA, and BPDA is better than PMDA. Therefore, the dianhydride containing the ester group is the important raw material for causing the low dissipation factor.

However, as known from Example 9 to Example 11, the polyimide film containing the ester group has the poor film forming property, the reason may be that the para-position of the amine group is an electron-withdrawing ester group, resulting in the poor reactivity of the amine group. As known from Example 7 and Example 8, the diamine containing the ester group can be formed the polyimide with the highly reactive 6FDA, but the dissipation factor is 0.016 and 0.011, respectively, which do not have the low dissipation factor characteristic.

In conclusion, the polyimide of the present disclosure synthesized from 3,4′-ODA diamine monomer and TAHQ dianhydride monomer containing the ester group has the characteristics of the low dielectric constant and the low dissipation factor. Moreover, the prepared flexible copper clad laminate thereof can pass the heat resistant of solder float test, which is favorable to apply the production of 5G high-frequency transmission printed circuit flexible boards to be satisfied with the requirement of the industry.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A low-dissipation flexible copper clad laminate, comprising:
a copper foil; and
a polyimide film attached to the copper foil, wherein the polyimide film comprises a polyimide, and the polyimide has a structure represented by formula (I): 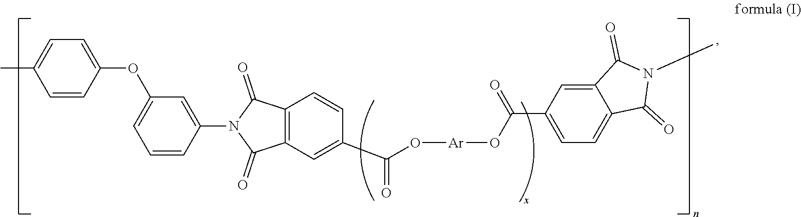
wherein Ar is a divalent organic group containing an aromatic ring, x is 0 or 1, n is an average value, and n is greater than 30 and less than 500.

2. The low-dissipation flexible copper clad laminate of claim 1, wherein in the formula (I), Ar is a structure represented by formula (A), formula (B) or formula (C):

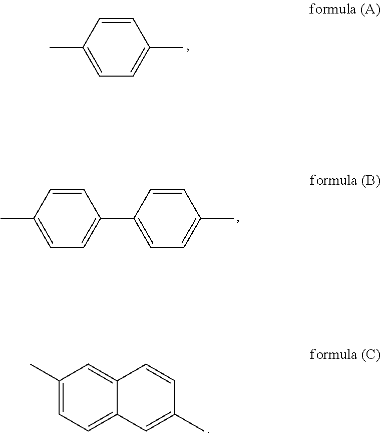

3. The low-dissipation flexible copper clad laminate of claim 2, wherein in the formula (I), when x is 1 and Ar is the structure represented by formula (A), the polyimide contained in the polyimide film has a structure represented by formula (I-A):

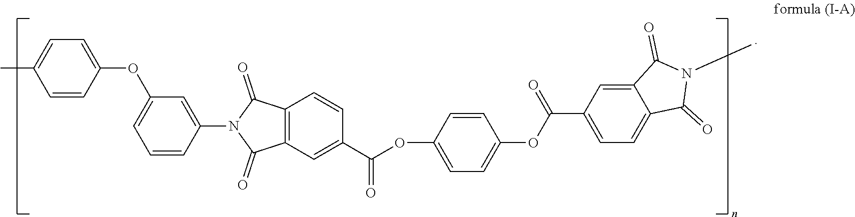

4. The low-dissipation flexible copper clad laminate of claim 3, wherein a dielectric constant of the polyimide film is 2.8 to 3.5.

5. The low-dissipation flexible copper clad laminate of claim 3, wherein a dissipation factor of the polyimide film is less than 0.0025.

6. A manufacturing method for a low-dissipation flexible copper clad laminate of claim 1, comprising:
performing a mixing step, wherein a diamine monomer represented by formula (i) is dissolved in an organic solvent, and then a dianhydride monomer represented by formula (ii) is added to form a polyamic acid solution: 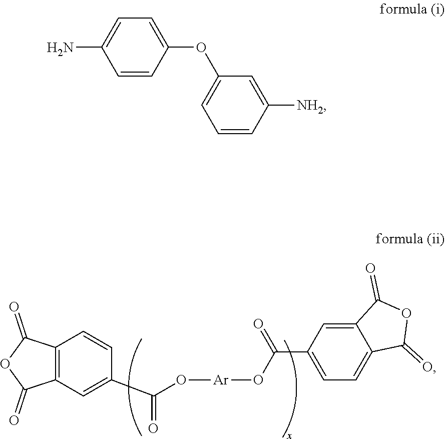
wherein Ar is the divalent organic group containing the aromatic ring, x is 0 or 1; and
performing a condensation reaction, wherein the polyamic acid solution is coated on the copper foil, and performed the heat and ring-closing to obtain the low-dissipation flexible copper clad laminate.

7. The manufacturing method of claim 6, wherein in the formula (ii), Ar is a structure represented by formula (A), formula (B) or formula (C):

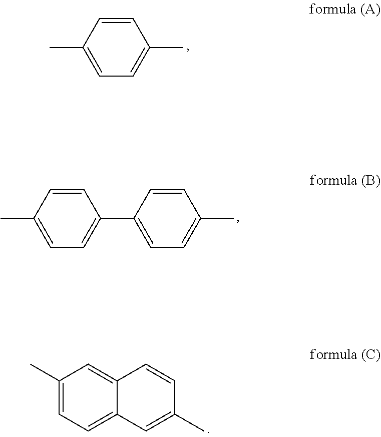

8. The manufacturing method of claim 6, wherein the organic solvent is dimethylacetamide, dimethylformamide, or N-methyl-2-pyrrolidone.

9. The manufacturing method of claim 6, wherein a molar ratio of the diamine monomer represented by formula (i) to the dianhydride monomer represented by formula (ii) is 0.9 to 1.1.

10. An electronic device comprising the low-dissipation flexible copper clad laminate of claim 1.
